(19) United States
(12) Patent Application Publication
(10) Pub. No.: US 2026/0150552 A1
(43) Pub. Date: May 28, 2026

(54) DISPLAY DEVICE

(71) Applicant: Magnolia White Corporation, Tokyo (JP)

(72) Inventors: Ryota TAKASAKI, Tokyo (JP); Sho YANAGISAWA, Tokyo (JP); Tomokazu ISHIKAWA, Tokyo (JP)

(73) Assignee: Magnolia White Corporation, Tokyo (JP)

(21) Appl. No.: 19/401,445

(22) Filed: Nov. 26, 2025

(30) Foreign Application Priority Data
Nov. 28, 2024 (JP) 2024-207396

(51) Int. Cl. H10K 59/80; H10K 59/12; H10K 59/122

(52) U.S. Cl. CPC H10K 59/871; H10K 59/1201; H10K 59/122

(57) ABSTRACT

According to one embodiment, a display device includes a substrate, an organic insulating layer, a rib layer, a partition, a stacked film, a sealing layer, and a first resin layer. The partition includes first and second partitions. The sealing layer includes first and second sealing layers. A first end portion of the second sealing layer in the surrounding area is between a second end portion of the organic insulating layer and a third end portion of the second partition. The first end portion has a thickness smaller than a thickness of the second sealing layer above the second partition and has a width equivalent to or greater than the thickness.

### CROSS-REFERENCE TO RELATED APPLICATIONS

This application is based upon and claims the benefit of priority from Japanese Patent Application No. 2024-207396, filed Nov. 28, 2024, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. This type of display devices demand a technique for improving the yield.

### BRIEF DESCRIPTION OF THE DRAWINGS

FIG. 1 is a view showing a configuration example of a display device according to an embodiment.

FIG. 2 is a schematic plan view showing an example of the layout of subpixels.

FIG. 3 is a schematic cross-sectional view of the display device along III-III line of FIG. 2.

FIG. 4 is a schematic plan view showing some elements of the display device.

FIG. 5 is a schematic cross-sectional view of the display device along V-V line of FIG. 4.

FIG. 6 is a schematic cross-sectional view in which the area in the vicinity of an end portion of a sealing layer is enlarged.

FIG. 7 is a schematic cross-sectional view showing another example applicable to the end portion of the sealing layer.

FIG. 8 is a flowchart showing an example of a manufacturing method of the display device of the embodiment.

FIG. 9A is a schematic cross-sectional view showing a manufacturing process of the display device.

FIG. 9B is a schematic cross-sectional view showing a process following the process shown in FIG. 9A.

FIG. 9C is a schematic cross-sectional view showing a process following the process shown in FIG. 9B.

FIG. 9D is a schematic cross-sectional view showing a process following the process shown in FIG. 9C.

FIG. 9E is a schematic cross-sectional view showing a process following the process shown in FIG. 9D.

FIG. 9F is a schematic cross-sectional view showing a process following the process shown in FIG. 9E.

FIG. 9G is a schematic cross-sectional view showing a process following the process shown in FIG. 9F.

FIG. 10 is a schematic plan view showing an area in which droplets of a resin layer are discharged.

FIG. 11 is a schematic cross-sectional view showing the configuration in the vicinity of the end portion of the sealing layer of the comparative example.

FIG. 12 is a schematic cross-sectional view in showing the configuration in the vicinity of the end portion of the sealing layer of the embodiment.

### DETAILED DESCRIPTION

In general, according to one embodiment, a display device includes a substrate having a display area including a plurality of subpixels and a surrounding area around the display area, an organic insulating layer provided above the substrate across the display area and the surrounding area, a rib layer provided above the organic insulating layer, a partition including a conductive lower portion provided above the rib layer and an upper portion having an end portion protruding relative to a side surface of the lower portion, a stacked film provided in the display area and the surrounding area and including at least an organic layer emitting light in response to application of a voltage, a sealing layer formed of an inorganic insulating material and covering the stacked film in the display area and the surrounding area, and a first resin layer covering the sealing layer. The partition includes a first partition surrounding each of the plurality of subpixels and a second partition provided above the organic insulating layer in the surrounding area. The sealing layer includes a first sealing layer provided in the display area and a second sealing layer provided in the surrounding area. A first end portion of the second sealing layer in the surrounding area is located between a second end portion of the organic insulating layer and a third end portion of the second partition in plan view. The first end portion has a thickness smaller than a thickness of the second sealing layer located above the second partition and has a width equivalent to or greater than the thickness of the second sealing layer.

The configuration of the embodiment can improve the yield of a display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. Z-direction is a normal to the plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

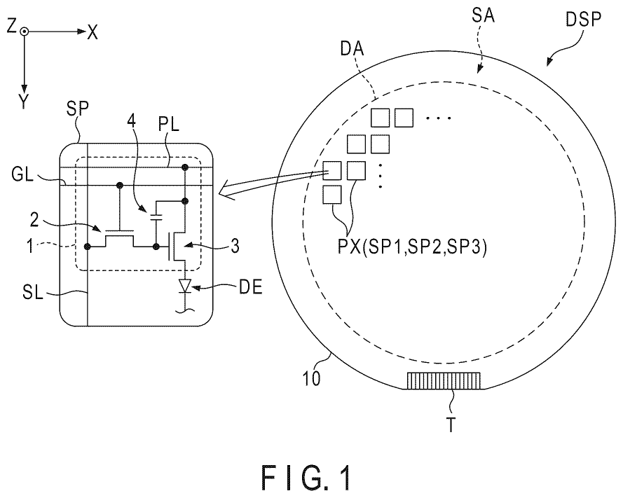

FIG. 1 is a view showing a configuration example of a display device DSP according to an embodiment. The display device DSP comprises an insulating substrate 10. The substrate 10 has a display area DA for displaying images and a surrounding area SA around the display area DA. The substrate 10 may be glass or a resinous film having flexibility.

In the present embodiment, each of the substrate 10 and the display area DA has a circular shape in plan view. The shape of each of the substrate 10 and the display area DA in plan view is not limited to the circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP displaying different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit board applying voltage and signals for driving the display device DSP is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A plurality of scanning lines GL supplying a scanning signal to the pixel circuit 1 of each subpixel SP, a plurality of signal lines SL supplying a video signal to the pixel circuit 1 of each subpixel SP, and a plurality of power lines PL are provided in the display area DA. In the example of FIG. 1, the scanning lines GL and the power lines PL extend in the X-direction, and the signal lines SL extend in the Y-direction.

A gate electrode of the pixel switch 2 is connected to the scanning line GL. One of a source electrode and a drain electrode of the pixel switch 2 is connected to the signal line SL. The other is connected to a gate electrode of the drive transistor 3 and the capacitor 4. In the drive transistor 3, one of a source electrode and a drain electrode is connected to the power line PL and the capacitor 4. The other is connected to the display element DE.

The configuration of the pixel circuit 1 is not limited to the example of the figure. For example, the pixel circuit 1 may comprise more thin-film transistors and capacitors.

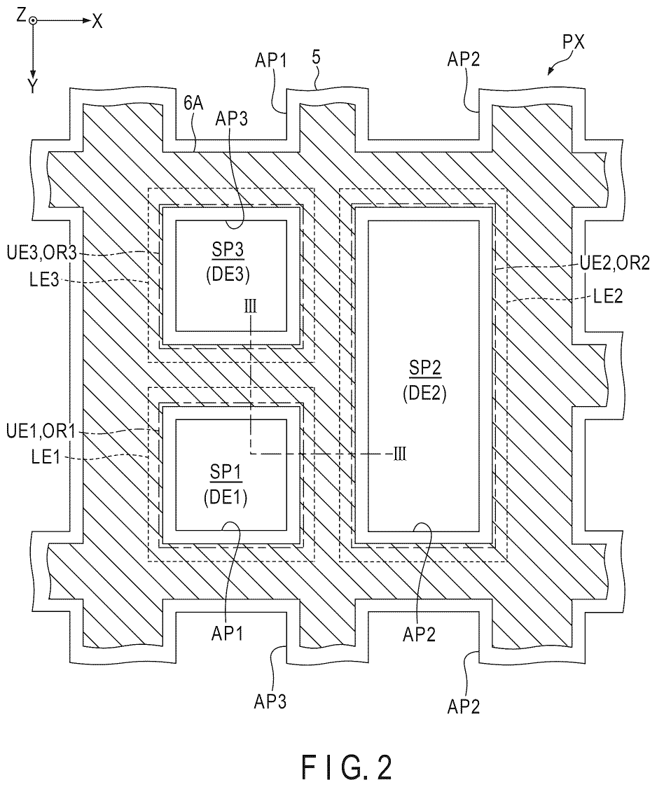

FIG. 2 is a schematic plan view showing an example of the layout of the subpixels SP1, SP2, and SP3 which constitute one pixel PX. In the example of FIG. 2, the subpixels SP1 and SP3 are arranged in the Y-direction. Further, the subpixels SP1 and SP3 are aligned with the subpixel SP2 in the X-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the respective subpixels SP1, SP2, and SP3. In the example of FIG. 2, the pixel apertures AP1 and AP3 are rectangles having the same planar size. In contrast, the pixel aperture AP2 is a rectangle extending longer in the Y-direction than the pixel apertures AP1 and AP3. The shape of the pixel apertures AP1, AP2, and AP3 is not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

Parts overlapping the pixel aperture AP1 of the lower electrode LE1, the upper electrode UE1, and the organic layer OR1 constitute a display element DE1 of the subpixel SP1. Parts overlapping the pixel aperture AP2 of the lower electrode LE2, the upper electrode UE2, and the organic layer OR2 constitute a display element DE2 of the subpixel SP2. Parts overlapping the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6A (the first partition) is provided above the rib layer 5. The partition 6A functions as lines applying common voltage to the upper electrodes UE1, UE2, and UE3. The partition 6A entirely overlaps the rib layer 5 and has the same planar shape as the rib layer 5. Further, the partition 6A surrounds each of the pixel apertures AP1, AP2, and AP3.

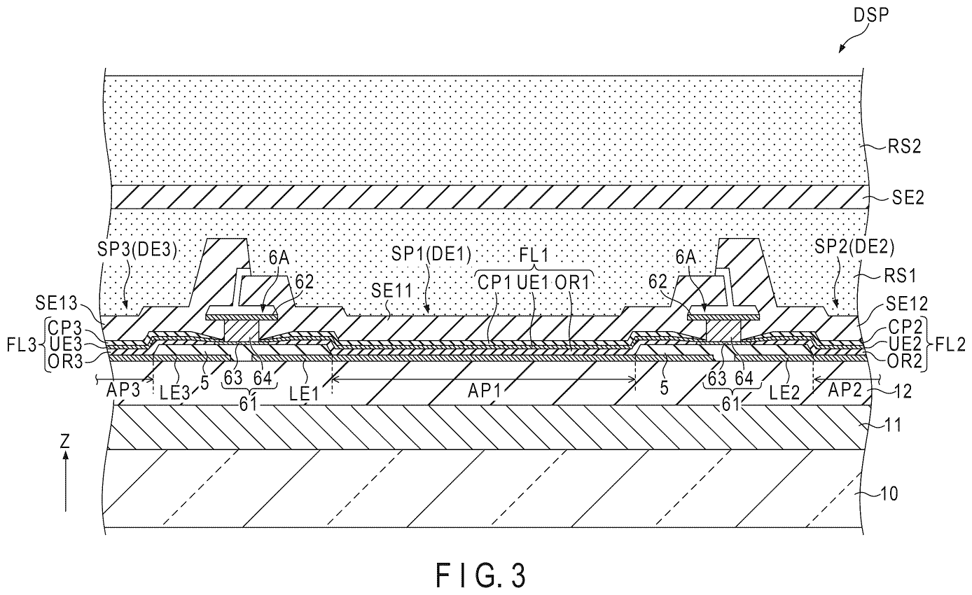

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, the scanning lines G, the signal lines S, and the power lines PL shown in FIG. 1. The circuit layer 11 is covered with an organic insulating layer 12. The organic insulating layer 12 functions as a planarization film planarizing irregularities formed by the circuit layer 11.

Each of the lower electrodes LE1, LE2, and LE3 is provided on the organic insulating layer 12. The rib layer 5 is provided over the organic insulating layer 12 and the lower electrodes LE1, LE2, and LE3. End portions of each of the lower electrodes LE1, LE2, and LE3 are covered with the rib layer 5.

The partition 6A includes a conductive lower portion 61 provided on the rib layer 5 and an upper portion 62 provided on the lower portion 61. The upper portion 62 has a width greater than that of the lower portion 61. This configuration causes both end portions of the upper portion 62 to protrude relative to the side surfaces of the lower portion 61. That is, the partition 6A has an overhang shape in which both end portions of the upper portion 62 protrude relative to the side surfaces of the lower portion 61.

In the example of FIG. 3, the lower portion 61 has a bottom layer 63 and a stem layer 64. The bottom layer 63 is thinner than the stem layer 64 and is located between the stem layer 64 and the rib layer 5. Both end portions of the bottom layer 63 respectively protrude relative to both side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portion 61 of the partition 6A.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the respective organic layers OR1, OR2, and OR3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12, and SE13 (the first sealing layers), which respectively cover the stacked films FL1, FL2, and FL3 are respectively provided in the subpixels SP1, SP2, and SP3. More specifically, the sealing layer SE11 continuously covers the cap layer CP1 and the partition 6A around the subpixel SP1. The sealing layer SE12 continuously covers the cap layer CP2 and the partition 6A around the subpixel SP2. The sealing layer SE13 continuously covers the cap layer CP3 and the partition 6A around the subpixel SP3.

In the example of FIG. 3, the sealing layers SE11 and SE12 overlap each other above the partition 6A between the subpixels SP1 and SP2 in the Z-direction. Further, the sealing layers SE11 and SE13 overlap each other above the partition 6A between the subpixels SP1 and SP3 in the Z-direction. The configuration is not limited to this example. The sealing layers SE11, SE12, and SE13 may be spaced apart from each other above the partition 6A.

For example, gaps are formed between the respective sealing layers SE11, SE12, and SE13 and the upper portion 62 of the partition 6A. The stacked films FL1, FL2, and FL3 may be provided in at least part of these gaps.

The sealing layers SE11, SE12, and SE13 are covered with a resin layer RS1 (the first resin layer). The resin layer RS1 is covered with a sealing layer SE2 (the third sealing layer). The sealing layer SE2 is covered with a resin layer RS2 (the second resin layer). The resin layers RS1 and RS2 and the sealing layer SE2 are continuously provided in at least the entire display area DA and partly extend in the surrounding area SA as well.

A cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). In one example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer formed of, for example, silver and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is formed of a plurality of thin films including a light emitting layer. As an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z-direction. The organic layers OR1, OR2, and OR3 each may comprise other structures such as a tandem structure including a plurality of light emitting layers.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

For example, each of the bottom layer 63 and the stem layer 64 of the partition 6A is formed of, for example, a metal material. For the metal material of the bottom layer 63, for example, molybdenum, titanium, titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

For example, the upper portion 62 of the partition 6A includes a stacked layer structure comprising a lower layer formed of a metal material and an upper layer formed of a conductive oxide. In this case, for the metal material of the lower layer, titanium, a titanium nitride, molybdenum, tungsten, a molybdenum-tungsten alloy, or a molybdenum-niobium alloy may be used. Further, for a conductive oxide of the upper layer, an ITO or an IZO may be used. The upper portion 62 may comprise three or more layers. Alternatively, the upper portion 62 may be formed of a single layer. The upper portion 62 may further include a layer formed of an insulating material.

The partition 6A is supplied with common voltage. This common voltage is applied to each of the upper electrodes UE1, UE2, and UE3 in contact with the lower portion 61. Pixel voltages according to the video signals of the signal lines SL are applied to the lower electrodes LE1, LE2, and LE3 through the respective pixel circuits 1 provided in the subpixels SP1, SP2, and SP3.

The organic layers OR1, OR2, and OR3 emit light in response to the application of a voltage. More specifically, when a potential difference is formed between the lower electrode LE1 and the upper electrode UE1, the light emitting layer of the organic layer OR1 emits light in the blue wavelength range. When a potential difference is formed between the lower electrode LE2 and the upper electrode UE2, the light emitting layer of the organic layer OR2 emits light in the green wavelength range. When a potential difference is formed between the lower electrode LE3 and the upper electrode UE3, the light emitting layer of the organic layer OR3 emits light in the red wavelength range.

In another example, the light emitting layers of the organic layers OR1, OR2, and OR3 may emit light of the same color (for example, white). In this case, the display device DSP may comprise a color filter that converts the light emitted from the light emitting layers into light of the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

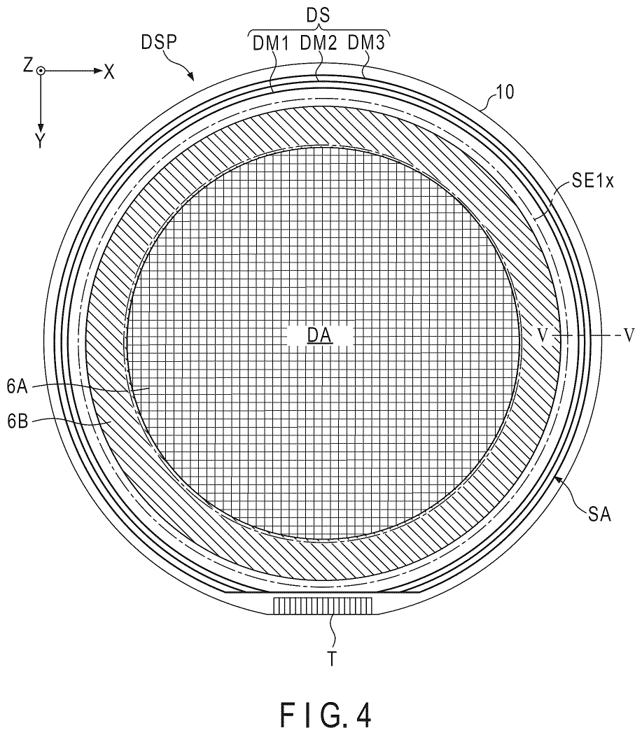

FIG. 4 is a schematic plan view showing some elements of the display device DSP. The partition 6A having a lattice shape is provided in the display area DA. Further, in the surrounding area SA, a partition 6B (the second partition), a sealing layer SE1x (the second sealing layer), and a dam structure DS are provided. FIG. 4 shows the partition 6B with a hatched pattern.

For example, the partition 6B, the sealing layer SE1x, and the dam structure DS have a ring shape surrounding the display area DA. Although not illustrated in FIG. 4, the partition 6B has many apertures or is divided into many segments by slits.

The sealing layer SE1x entirely covers the partition 6B. Part of the partition 6B may be exposed from the sealing layer SE1x.

The dam structure DS includes a dam portion DM1 surrounding the partition 6B and the sealing layer SE1x, a dam portion DM2 surrounding the dam portion DM1, and a dam portion DM3 surrounding the dam portion DM2. The number of dam portions that the dam structure DS comprises is not limited to three.

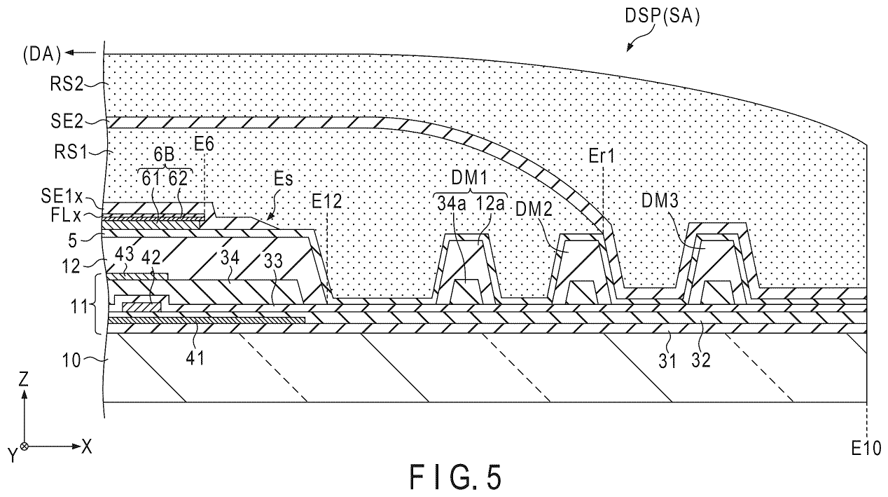

FIG. 5 is a schematic cross-sectional view of the display device DSP along V-V line of FIG. 4. The circuit layer 11 shown in FIG. 3 has inorganic insulating layers 31, 32, and 33 formed of inorganic insulating materials, an organic insulating layer 34 formed of an organic insulating material, and metal layers 41, 42, and 43. The inorganic insulating layer 31 covers the upper surface of the substrate 10. The metal layer 41 is provided on the inorganic insulating layer 31. The inorganic insulating layer 32 covers the metal layer 41. The metal layer 42 is provided on the inorganic insulating layer 32. The inorganic insulating layer 33 covers the metal layer 42. The organic insulating layer 34 covers the inorganic insulating layer 33. The metal layer 43 is provided on the organic insulating layer 34 and is covered with the organic insulating layer 12.

The dam portions DM1, DM2, and DM3 are provided outside the end portion of the organic insulating layer 12 (the right side of the figure). In the example of FIG. 5, the dam portion DM1 includes a first layer 34a formed in the same layer and of the same material as the organic insulating layer 34 and a second layer 12a formed in the same layer and of the same material as the organic insulating layer 12. The dam portions DM2 and DM3 are also formed of the first layer 34a and the second layer 12a.

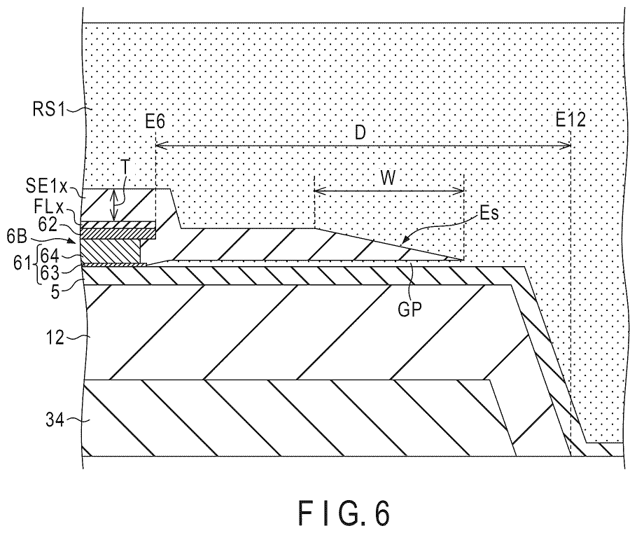

The rib layer 5 continuously covers the organic insulating layer 12 and the dam portions DM1, DM2, and DM3. The partition 6B is provided above the organic insulating layers 12 and 34. In the same manner as the partition 6A, the partition 6B includes the lower portion 61 provided on the rib layer 5 and the upper portion 62 provided on the lower portion 61. In the same manner as the lower portion 61 of the partition 6A, the lower portion 61 of the partition 6B has the bottom layer 63 and the stem layer 64 (refer to FIG. 6).

For example, a stacked film FLx is provided on the upper portion 62 of the partition 6B. The stacked film FLx and the partition 6B are covered with the sealing layer SE1x. The stacked film FLx is formed by the same process and of the same material as any of the stacked films FL1, FL2, and FL3 shown in FIG. 3. The sealing layer SE1x is formed by the same process and of the same material as any of the sealing layers SE11, SE12, and SE13 shown in FIG. 3. In the present embodiment, the stacked film FLx and the sealing layer SE1x are assumed to be formed by the same process and of the same material as the stacked film FL3 and the sealing layer SE13, respectively. That is, the stacked film FLx includes the upper electrode UE3, the organic layer OR3, and the cap layer CP3.

An end portion Es (the first end portion) of the sealing layer SE1x is located between an end portion E12 (the second end portion) of the organic insulating layer 12 and an end portion E6 (the third end portion) of the partition 6B in plan view. That is, the end portion Es is located above the organic insulating layers 12 and 34.

Above the sealing layer SE1x, the resin layer RS1, the sealing layer SE2, and the resin layer RS2 shown in FIG. 3 are provided. The resin layer RS1 covers the sealing layer SE1x and the rib layer 5. In the manufacturing of the display device DSP, the dam portions DM1, DM2, and DM3 function to dam the resin layer RS1 before curing. In the example of FIG. 5, an end portion Er1 of the resin layer RS1 is located above the dam portion DM2. That is, the resin layer RS1 partly covers the dam portions DM1 and DM2. The position of the end portion Er1 is not limited to this example.

The sealing layer SE2 covers the end portion Er1 of the resin layer RS1. The sealing layer SE2 contacts the rib layer 5 in an area located outside the end portion Er1 (the right side in the figure). The resin layer RS2 entirely covers the sealing layer SE2.

The cross section structure shown in FIG. 5 is applicable to any positions in the surrounding area SA. The configuration of the surrounding area SA is not necessarily limited to the configuration shown in FIG. 5. For example, a configuration different from the one shown in FIG. 5 may be adopted in the vicinity of the terminal portion T.

FIG. 6 is a schematic cross-sectional view in which the area in the vicinity of the end portion Es of the sealing layer SE1x is enlarged. The end portion Es is formed to have a thickness smaller than a thickness of other parts of the sealing layer SE1x, for example, is smaller than a thickness T of a part located above the partition 6B. Furthermore, the end portion Es has a width W equivalent to or greater than the thickness T (W≥T).

In the example of FIG. 6, the end portion Es has a tapered shape whose thickness gradually decreases. That is, an upper surface of the end portion Es is an inclined surface descending toward the end portion E12 of the organic insulating layer 12. The upper surface need not be a plane surface and may have curvature. The end portion Es is entirely covered with the resin layer RS1.

Preferably, the width W of the end portion Es is as large as possible within a range not exceeding a distance D between the end portion E12 of the organic insulating layer 12 and the end portion E6 of the partition 6B in plan view. In one example, the width W is at least one third of the distance D (W≥⅓×D).

In the example of FIG. 6, a gap GP is formed between the rib layer 5 and the end portion Es. The gap GP corresponds to a part not having the stacked film FLx between the rib layer 5 and the sealing layer SE1x in an area in which the rib layer 5 and the sealing layer SE1x are stacked without the partition 6B. The gap GP has a height equivalent to the thickness of the stacked film FLx. The gap GP is formed by removing the stacked film FLx during manufacturing of the display device DSP.

As shown in the figure, the gap GP may be formed in the entire area between the rib layer 5 and the sealing layer SE1x and may be filled with the resin layer RS1. At least part of the gap GP may be a void. The gap GP need not be formed in the entire area between the rib layer 5 and the sealing layer SE1x. In a part indicated as the gap GP in FIG. 6, the stacked film FLx, part of layers constituting the stacked film FLx, or a material altered from these layers during manufacturing of the display device DSP may be present.

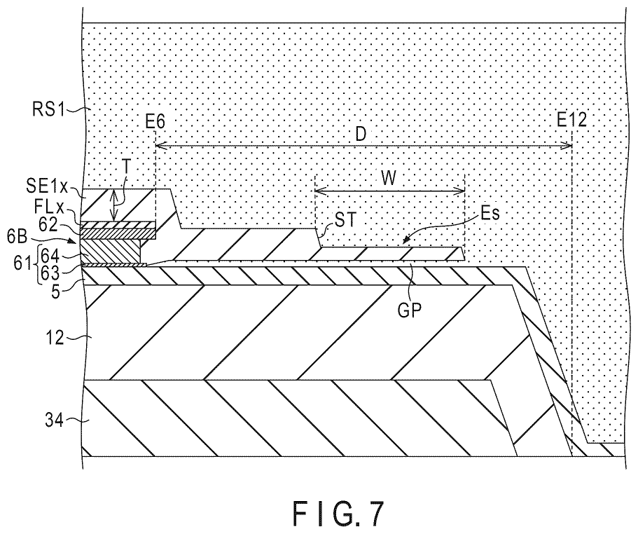

FIG. 7 is a schematic cross-sectional view showing another example applicable to the end portion Es of the sealing layer SE1x. In this example, the end portion Es has a substantially constant thickness over most of its area. From another perspective, the upper surface of the end portion Es is a flat surface parallel to the upper surfaces of the rib layer 5 and the organic insulating layer 12. Further, a step ST is formed between the end portion Es and other parts of the sealing layer SE1x. The thickness of the end portion Es may change in two or more stages.

In the example of FIG. 7, the end portion Es is also formed to be thinner than the thickness T and has the width W equivalent to or greater than the thickness T. Further, in one example, the width W is at least one third of the distance D (W≥⅓×D).

The following will describe an example of the manufacturing method of the display device DSP.

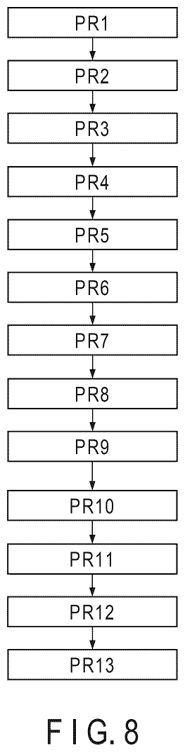

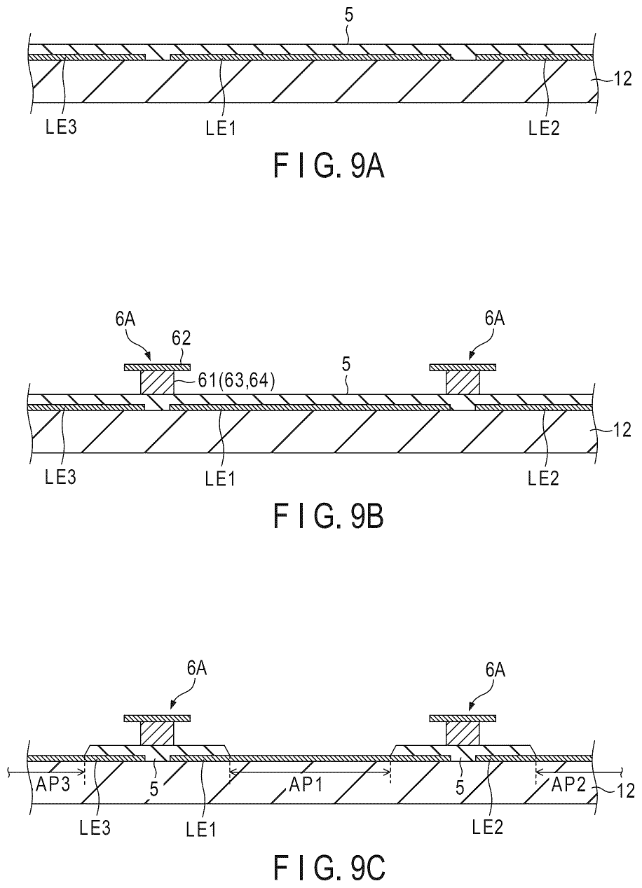

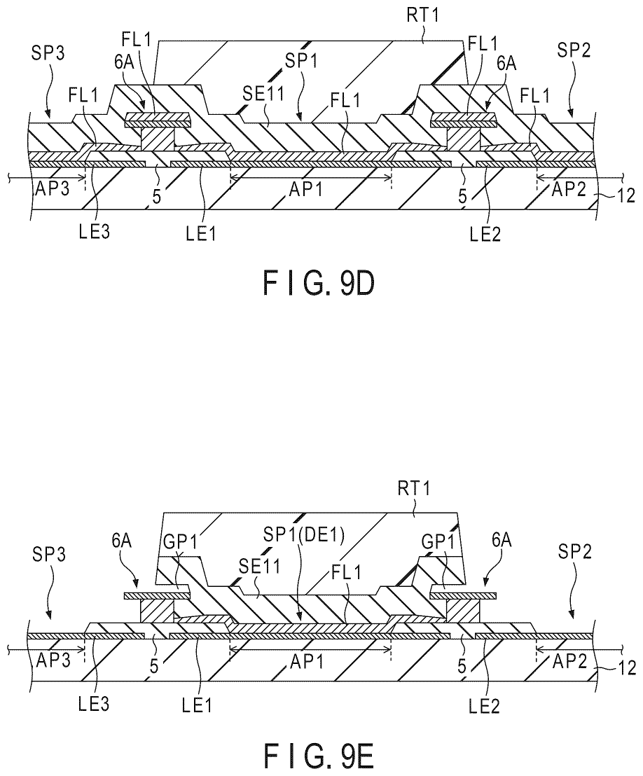

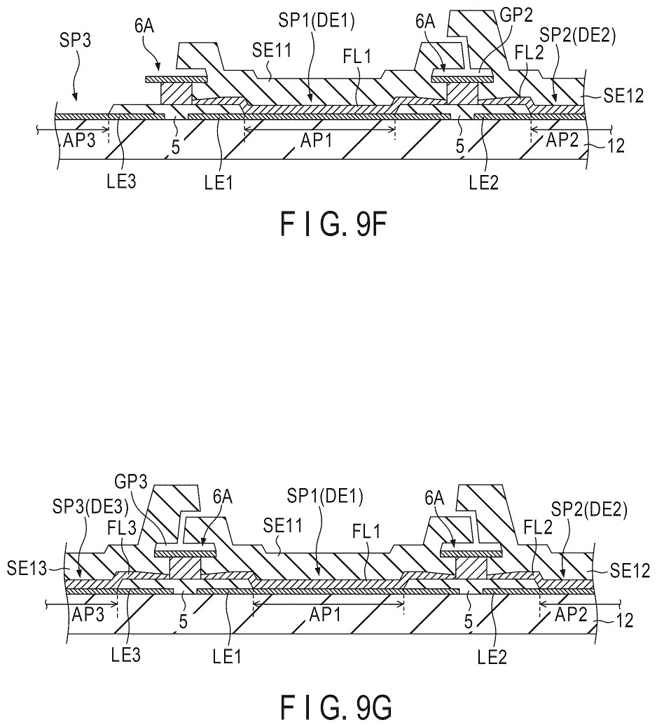

FIG. 8 is a flowchart showing an example of the manufacturing method of the display device DSP. FIG. 9A to FIG. 9G are schematic cross-sectional views showing the manufacturing processes of the display device DSP. FIG. 9A to FIG. 9G mainly focus on the display area DA and omit the illustration of elements under the organic insulating layer 12.

In the manufacturing of the display device DSP, a large mother substrate for forming the plurality of display devices DSP is prepared. The circuit layer 11 is formed above the substrate 10 of the mother substrate (the process PR1 in FIG. 8). Further, the organic insulating layer 12 covering the circuit layer 11 is formed (the process PR2 in FIG. 8). At this time, the dam portions DM1, DM2, and DM3 are also formed.

After the process PR2, as shown in FIG. 9A, the lower electrodes LE1, LE2, and LE3 are formed on the organic insulating layer 12 (the process PR3 in FIG. 8). Further, the rib layer 5 covering the lower electrodes LE1, LE2, and LE3 is formed (the process PR4 in FIG. 8). At this time, the pixel apertures AP1, AP2, and AP3 are not provided in the rib layer 5. The rib layer 5 can be formed by chemical vapor deposition (CVD).

After the formation of the rib layer 5, as shown in FIG. 9B, the partition 6A is formed on the rib layer 5 (the process PR5 in FIG. 8). For example, in the formation of the partition 6A, material layers of the bottom layer 63, the stem layer 64, and the upper portion 62 are formed in the entire mother substrate. Further, a resist having the shape of the partition 6A is provided on these layers. Etching each of the layers using this resist as a mask can form the partition 6A having an overhang shape and open in each of the subpixels SP1, SP2, and SP3. The partition 6B in the surrounding area SA is formed simultaneously with the partition 6A by the same process.

Next, as shown in FIG. 9C, the pixel apertures AP1, AP2, and AP3 are formed in the rib layer 5 (the process PR6 in FIG. 8). The pixel apertures AP1, AP2, and AP3 may be formed before the formation of the partition 6A.

After the process PR6, the process for forming the display element DE1 is performed (the process PR7 in FIG. 8). As shown in FIG. 9D, in the formation of the display element DE1, the stacked film FL1 and the sealing layer SE11 are formed first on the entire substrate. As shown in FIG. 3, the stacked film FL1 includes the organic layer OR1 contacting the lower electrode LE1 through the pixel aperture AP1, the upper electrode UE1 covering the organic layer OR1, and the cap layer CP1 covering the upper electrode UE1. For example, the organic layer OR1, the upper electrode UE1, and the cap layer CP1 may be formed by vapor deposition. For example, the sealing layer SE11 may be formed by CVD.

The stacked film FL1 and the sealing layer SE11 are formed not only in the display area DA but also in the surrounding area SA. The partitions 6A and 6B having an overhang shape divide the stacked film FL1. The sealing layer SE11 continuously covers these parts into which the stacked film FL1 has been divided, and the partitions 6A and 6B.

Subsequently, the stacked film FL1 and the sealing layer SE11 are patterned. As shown in FIG. 9D, a resist RT1 is provided on the sealing layer SE11 in this patterning. The resist RT1 covers the subpixel SP1 and part of the partition 6 around the subpixel SP1.

Thereafter, the etching process using the resist RT1 as a mask is performed. As shown in FIG. 9E, this etching process removes parts exposed from the resist RT1 of the stacked film FL1 and the sealing layer SE11. Thus, the display element DE1 is formed in the subpixel SP1.

For example, in the surrounding area SA, the stacked film FL1 and the sealing layer SE11 are removed by the etching process. This etching process may include wet etching and dry etching performed in order for the sealing layer SE11, the cap layer CP1, the upper electrode UE1, and the organic layer OR1. After these etching processes, the resist RT1 is removed (stripped).

During the etching process, the stacked film FL1 in the vicinity of the end portion of the sealing layer SE11 may be removed to form the gap GP1 below this end portion.

After the process PR7, the process for forming the display element DE2 is performed (the process PR8 in FIG. 8). The display element DE2 can be formed by the same procedure as that of the display element DE1. That is, in the formation of the display element DE2, the stacked film FL2 and the sealing layer SE12 are formed on the entire substrate. As shown in FIG. 3, the stacked film FL2 includes the organic layer OR2 contacting the lower electrode LE2 through the pixel aperture AP2, the upper electrode UE2 covering the organic layer OR2, and the cap layer CP2 covering the upper electrode UE2. The organic layer OR2, the upper electrode UE2, and the cap layer CP2 may be formed by, for example, vapor deposition. The sealing layer SE12 may be formed by, for example, CVD.

The stacked film FL2 and the sealing layer SE12 are formed not only in the display area DA but also in the surrounding area SA. The partitions 6A and 6B having an overhang shape divide the stacked film FL2. The sealing layer SE12 continuously covers these parts into which the stacked film FL2 has been divided, and the partitions 6A and 6B.

Subsequently, the stacked film FL2 and the sealing layer SE12 are patterned by etching processes. As shown in FIG. 9F, thus, the display element DE2 is formed in the subpixel SP2. For example, in the surrounding area SA, the stacked film FL2 and the sealing layer SE12 are removed by the etching process. During the etching process, the stacked film FL2 in the vicinity of an end portion of the sealing layer SE12 may be removed to form a gap GP2 below this end portion.

After the process PR8, the process for forming the display element DE3 is performed (the process PR9 in FIG. 8). The display element DE3 can be formed by the same procedures as those of the display elements DE1 and DE2. That is, in the formation of the display element DE3, the stacked film FL3 and the sealing layer SE13 are formed on the entire substrate. As shown in FIG. 3, the stacked film FL3 includes the organic layer OR3 contacting the lower electrode LE3 through the pixel aperture AP3, the upper electrode UE3 covering the organic layer OR3, and the cap layer CP3 covering the upper electrode UE3. The organic layer OR3, the upper electrode UE3, and the cap layer CP3 may be formed by, for example, vapor deposition. The sealing layer SE13 may be formed by, for example, CVD.

The stacked film FL3 and the sealing layer SE13 are formed not only in the display area DA but also in the surrounding area SA. The partitions 6A and 6B having an overhang shape divide the stacked film FL3. The sealing layer SE13 continuously covers these parts into which the stacked film FL3 has been divided, and the partitions 6A and 6B.

Subsequently, the stacked film FL3 and the sealing layer SE13 are patterned by etching processes. As shown in FIG. 9G, the display element DE3 is thereby formed in the subpixel SP3.

For example, in most of the surrounding area SA, the stacked film FL3 and the sealing layer SE13 are removed by the etching process. Parts of the stacked film FL3 and the sealing layer SE13 that cover the partition 6B remain. These remaining parts correspond to the stacked film FLx and the sealing layer SE1x.

During the etching process, the stacked film FL3 in the vicinity of an end portion of the sealing layer SE13 may be removed to form a gap GP3 below this end portion. Further, the stacked film FL3 in the vicinity of the end portion Es of the sealing layer SE1x in the surrounding area SA may also be removed to form the gaps GP shown in FIG. 6 and FIG. 7.

To embody the end portion Es having the shape shown in FIG. 6, a method using a gray-tone mask may be adopted for exposure of a resist used in etching the sealing layer SE1x (the sealing layer SE13). That is, providing a lot of fine slits in a part of the mask corresponding to the end portion Es with the interval of them gradually decreasing toward a tip side of the end portion Es and exposing a resist (for example, a positive resist) through the slits can form a resist whose thickness gradually decreases. Further, etching the sealing layer SE1x using this resist can form the end portion Es that has a tapered shape whose thickness gradually decreases.

In contrast, to embody the end portion Es having the shape shown in FIG. 7, a method using a half-tone mask may be adopted for exposure of a resist used in etching the sealing layer SE1x (the sealing layer SE13). That is, using a mask whose transmittance is adjusted to allow a part corresponding to the end portion Es to be exposed at low intensity can form a resist in which a part corresponding to the end portion Es is thin. Etching the sealing layer SE1x using this resist can form the end portion Es whose thickness gradually decreases compared to other parts.

Here, the present embodiment assumes that the display elements DE1, DE2, and DE3 are formed in this order. However, the display elements DE1, DE2, and DE3 may be formed in another order.

After the process PR9, the resin layer RS1 is formed by an inkjet method (the process PR10 in FIG. 8). Then, for example, the sealing layer SE2 is formed by CVD (the process PR11 in FIG. 8).

After the process PR11, the resin layer RS2 covering the sealing layer SE2 is formed by an inkjet method (the process PR12 in FIG. 8). After the formation of the resin layer RS2, parts corresponding to the display devices DSP are cut out from the mother substrate (the process PR13 in FIG. 8). The display device DSP is completed by the manufacturing method at least including these processes.

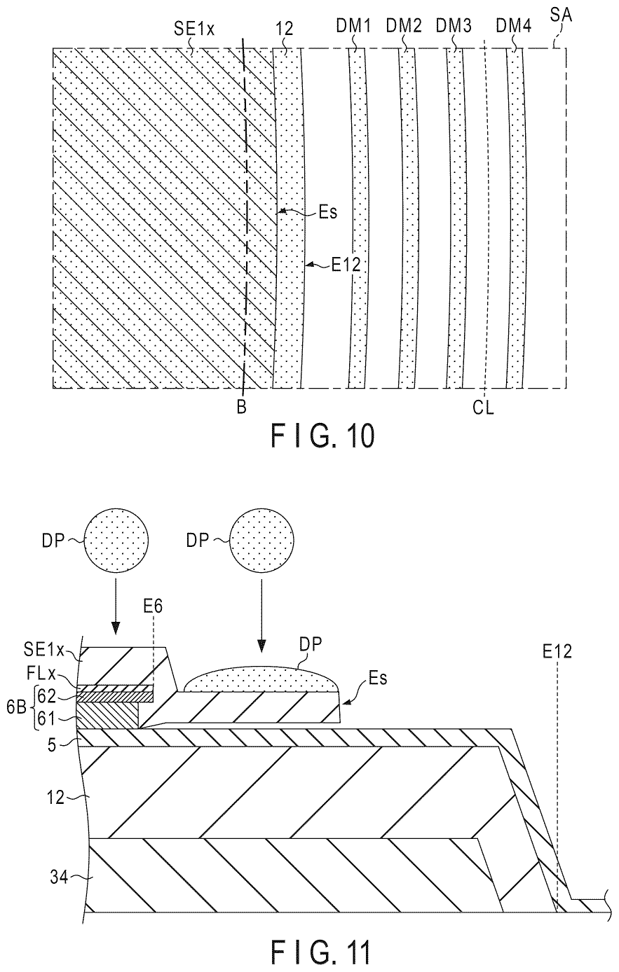

FIG. 10 is a schematic plan view showing an area in which droplets of the resin layer RS1 are discharged in the process PR10. This figure also shows the organic insulating layer 12, the sealing layer SE1x, the dam portions DM1, DM2, and DM3, and a cut line CL in the process PR13. A dam portion DM4 is provided outside the cut line CL to dam the droplets of the resin layer RS2 applied in the process PR12. The structure of the dam portion DM4 is the same as those of the dam portions DM1, DM2, and DM3.

An outer edge B of an area in which droplets of the resin layer RS1 are discharged overlaps the sealing layer SE1x. Droplets having adhered to the surface of the sealing layer SE1x spread by wetting toward the dam portion DM1 and are dammed by the dam portion DM2 beyond the dam portion DM1. The spreading of the droplets may stop short of the dam portion DM2 at some locations or may slightly pass the dam portion DM2 at some locations.

The area in which the droplets of the resin layer RS2 are discharged may be located closer to the cut line CL than the outer edge B. These droplets pass beyond the cut line CL and are dammed by the dam portion DM4. In the process PR13, for example, laser cutting cuts the substrate 10 together with the resin layer RS2.

The following will describe some effects achieved by the display device DSP according to the present embodiment.

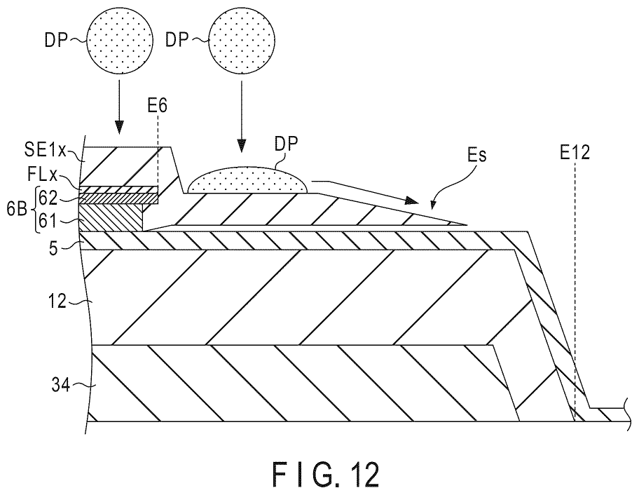

FIG. 11 is a schematic cross-sectional view showing the configuration in the vicinity of the end portion Es of the sealing layer SE1x of the comparative example of the present embodiment. FIG. 12 is a schematic cross-sectional view showing the configuration in the vicinity of the end portion Es of the sealing layer SE1x of the comparative example of the present embodiment.

In the comparative example shown in FIG. 11, the end portion Es is steep, like the end portion of the sealing layer SE13 in the display area DA (refer to FIG. 3). The droplets DP of the resin layer RS1 discharged in the process PR10 spread by wetting over the sealing layer SE1x. However, the end portion Es is steep and thus may potentially prevent the droplets from passing over the end portion Es due to the surface tension. In that case, defective sealing by the resin layer RS1 occurs. Further, when touch panel wiring and the like are provided above the resin layer RS1, a step at a defective sealed portion may cause disconnection. Further, residues of a metal material of wiring may remain where the metal material should originally be removed.

As a method for suppressing such defective sealing, one could discharge the droplets DP over an area further outside than the end portion Es of the sealing layer SE1x. Design constraints may preclude such a configuration. Considering wetting spread of the droplets DP, a distance between the outer edge B (refer to FIG. 10) of the discharge area and the dam portion DM1 must be kept equivalent to or greater than a prescribed distance. The partition 6B has a function of suppressing stripping of the stacked films FL1, FL2, and FL3 and the sealing layers SE11, SE12, and SE13 formed in the surrounding area SA during the manufacturing of the display device DSP. Thus, the partition 6B preferably extends as close as possible to the dam portion DM1. Furthermore, the sealing layer SE1x is preferably formed to cover the partition 6B. In view of these items, positional relationships among the end portion E12 of the organic insulating layer 12, the end portion E6 of the partition 6B, and the end portion Es of the sealing layer SE1x are constrained. Thus, providing the outer edge B of the discharge area of the droplets DP outside the end portion Es may be difficult.

In contrast, as in the configuration of the present embodiment shown in FIG. 12, the tapered end portion Es facilitates wetting spread of the droplets DP beyond the end portion Es. Thus, the resin layer RS1 having a favorable shape can be formed, and yield of the display device DSP can be improved. In particular, as described with reference to FIG. 6, when the width W of the end portion Es is at least one third of the distance D between the end portion E12 of the organic insulating layer 12 and the end portion E6 of the partition 6B, the end portion Es has a relatively gentle tapered shape, which is suitable. The effects described with reference to FIG. 12 are also achievable with the end portion Es having the shape shown in FIG. 7.

In the embodiments above, the term “partition” includes various structures having an overhang shape. Even when the overhang-shaped structure has a shape different from the partition disclosed in the embodiments, a part protruding laterally corresponds to the “upper portion,” and a recessed portion below that corresponds to the “lower portion.”

All of the display devices that can be implemented by a person of ordinary skill in the art through arbitrary design changes to the display device disclosed above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is

1. A display device, comprising:
a substrate having a display area including a plurality of subpixels and a surrounding area around the display area;
an organic insulating layer provided above the substrate across the display area and the surrounding area;
a rib layer provided above the organic insulating layer;
a partition including a conductive lower portion provided above the rib layer and an upper portion having an end portion protruding relative to a side surface of the lower portion;
a stacked film provided in the display area and the surrounding area and including at least an organic layer emitting light in response to application of a voltage;
a sealing layer formed of an inorganic insulating material and covering the stacked film in the display area and the surrounding area; and
a first resin layer covering the sealing layer, wherein
the partition includes a first partition surrounding each of the plurality of subpixels and a second partition provided above the organic insulating layer in the surrounding area,
the sealing layer includes a first sealing layer provided in the display area and a second sealing layer provided in the surrounding area,
a first end portion of the second sealing layer in the surrounding area is located between a second end portion of the organic insulating layer and a third end portion of the second partition in plan view, and
the first end portion has a thickness smaller than a thickness of the second sealing layer located above the second partition and has a width equivalent to or greater than the thickness of the second sealing layer.

2. The display device of claim 1, wherein
the first end portion has a tapered shape whose thickness gradually decreases.

3. The display device of claim 1, wherein
an upper surface of the first end portion is an inclined surface descending toward the second end portion.

4. The display device of claim 1, wherein
an upper surface of the first end portion is a flat surface parallel to an upper surface of the rib layer.

5. The display device of claim 4, wherein
a step is formed between the first end portion and remaining parts of the second sealing layer.

6. The display device of claim 1, wherein
the width of the first end portion is at least one third of a distance between the second end portion and the third end portion in plan view.

7. The display device of claim 1, wherein
the organic insulating layer includes a first organic insulating layer and a second organic insulating layer covering the first organic insulating layer, and
the first end portion is located above the first organic insulating layer and the second organic insulating layer.

8. The display device of claim 1, wherein
the stacked film is provided between the second partition and the second sealing layer.

9. The display device of claim 1, wherein
the first end portion is located above the rib layer, and
a gap is formed between the rib layer and the first end portion.

10. The display device of claim 9, wherein
the gap has a height equivalent to a thickness of the stacked film.

11. The display device of claim 9, wherein
the first end portion is covered with the first resin layer.

12. The display device of claim 11, wherein
at least part of the gap is filled with the first resin layer.

13. The display device of claim 11, further comprising:
a third sealing layer formed of an inorganic insulating material and covering the first resin layer.

14. The display device of claim 13, wherein
the third sealing layer contacts the rib layer in an area outside an end portion of the first resin layer.

15. The display device of claim 13, further comprising:
a second resin layer covering the third sealing layer.

16. The display device of claim 1, further comprising:
a dam portion provided in the surrounding area and surrounding the organic insulating layer, wherein
the rib layer continuously covers the organic insulating layer and the dam portion.

17. The display device of claim 16, wherein
the dam portion includes a first dam portion surrounding the organic insulating layer and a second dam portion surrounding the first dam portion,
the rib layer covers the first dam portion and the second dam portion, and
the first resin layer covers at least the first dam portion.

18. The display device of claim 17, wherein
an end portion of the first resin layer is located above the second dam portion.

19. The display device of claim 18, further comprising:
a third sealing layer formed of an inorganic insulating material and covering the first resin layer, wherein
the third sealing layer contacts the rib layer in an area outside the second dam portion.

20. The display device of claim 1, wherein
each of the substrate and the display area has a circular shape, and
the second sealing layer has an annular shape surrounding the display area.
